(19) United States
(12) Patent Application Publication
(10) Pub. No.: US 2008/0186042 A1
(43) Pub. Date: Aug. 7, 2008

(54) PROBE CARD

(75) Inventor: Ki Don Ko, Gyeonggi-do (KR)

Correspondence Address: PEARNE & GORDON LLP, 1801 EAST 9TH STREET, SUITE 1200, CLEVELAND, OH, 44114-3108, US

(73) Assignee: WILLTECHNOLOGY CO., LTD., Gyeonggi-do (KR)

(21) Appl. No.: 12/026,823

(22) Filed: Feb. 6, 2008

(30) Foreign Application Priority Data
Feb. 7, 2007 (KR) 10-2007-0012757

(51) Int. Cl. G01R 1/067

(52) U.S. Cl. 324/762

(57) ABSTRACT

A probe card having a simple structure and an easy manufacturing process disclosed. The probe card includes a main substrate having a probe circuit pattern formed thereon; a needle fixing block provided with a connection plate located on a lower surface of the main substrate and a tip plate apart from and parallel to the connection plate; and a needle provided with an elastic bending portion located between the connection plate and the tip plate, a tip portion extending from a lower end of the elastic bending portion and being projected from a lower surface of the tip plate, and a connection portion extending from an upper end of the elastic bending portion and being electrically connected to the prove circuit pattern.

### FIELD OF THE INVENTION

The present disclosure relates to a non-contact type test apparatus. More particularly, the present invention relates to a probe card that can reduce the manufacturing cost with improved workability and productivity and provide easy maintenance and repair by simplifying a structure and manufacturing process thereof.

### BACKGROUND OF THE INVENTION

Generally, a semiconductor device is manufactured through a fabrication process for forming a pattern on a wafer and an assembly process for assembling the patterned wafer into packaged chips.

In order to detect defective chips in the wafer, an electrical die sorting (EDS) process for testing the electrical characteristics of the respective chips in the wafer, which intervenes between the fabrication process and the assembly process, is performed. The EDS process is mainly performed by a testing apparatus applying electrical signals to the chips constituting the wafer and detects the defective chips based on the signals returned from the chips in response to the applied electrical signals.

The EDS process is mainly performed by the testing apparatus called a probe card having a plurality of needles that apply the electrical signals to the pattern of the respective chips while contacting with the pattern. More particularly, the electrical characteristic test of the chips in the semiconductor wafer is typically performed in a manner that the needles of the probe card are to be in contact with electrode pads or circuit terminals of the chips in the semiconductor wafer, and predetermined current is applied through the needles to test the electrical characteristics of the respective chips.

If it is checked that the chips in the wafer are normal through the above test using the probe card, the manufacture of the semiconductor device is completed through a assembly process such as packaging and so on.

FIG. 1 is a sectional view illustrating the structure of a conventional probe card.

As shown in FIG. 1, the probe card 20 includes a main substrate 30 on which a probe circuit pattern is formed and a plurality of needles 50 mounted on a lower surface of the main substrate 30 so as to vertically contact with a plurality of electrode pads (or circuit terminals) formed on a wafer 10 as a test object. Further, each of the needles 50 is supported and fixed by a needle fixing block 40 that is fixedly installed on the lower surface of the main substrate 30 in a state that the needles 50 are electrically connected to the main substrate 30.

The needle fixing block 40 includes a connection plate 42 disposed apart from the lower surface of the main substrate 30 by a predetermined distance, and a tip plate 44 disposed apart from a lower surface of the connection plate 42. Each of the plates 42 and 44 is disposed in parallel to the main substrate 30. A fastening member 45 is fixed to the main substrate 30 through the plates 42 and 44 such that the alignment between the main substrate 30, the connection plate 42 and the tip plate 44 is maintained.

Each of the needles 50 passes through the connection plate 42 and the tip plate 44. One end of the needle 50 is extended to the main substrate 30, thereby being electrically connected to the probe circuit pattern of the main substrate 30 through a wire 32 fixed by soldering, and the other end of the needle 50 is extended to a lower surface of the tip plate 44 and projected to an outside of the needle fixing block 40 so that the needle 50 is in contact with the test object. Guide holes 42a, 44a and 31 are formed through the respective plates 42, 44 and the main substrate 30 so that the needle 50 passes through the guide holes 42a, 44a and 31. The guide holes 42a, 44a and 31 corresponding to the needle 50 are arranged on the same line. Also, the disposition of the needles 50 is firmly kept by a resin layer 46 made of epoxy and so on and to be formed on an upper surface of the connection plate 42.

In addition, in the center portion of the respective needle 50 that is disposed between the connection plate 42 and the tip plate 44, a bending portion 52 is formed such that the respective needle 50 elastically contacts the test object.

When a force is applied to the needle 50, the needle 50, which becomes in contact with the test object, is required to have a vertical elasticity. In accordance with the conventional needle 50, however, when the force is applied to the needle 50, the force acting on upper and lower portions of the bending portion 52 is dispersed, so that the needle 50 cannot make a vertical movement and cannot have only a vertical elasticity with respect to the test object. This can cause an unexpected movement of the needle 50, and thus the characteristic test of the object becomes uneasy.

The above-described unexpected movement of the needle 50 can be corrected by guide holes 42a, 44a, and 31 formed through the respective plates 42 and 44. The guide holes 42a, 44a, and 31 serve to correct the moving direction of the needle 50 so that the needle can make a vertical movement when the force is applied to the needle 50. Accordingly, the vertical movement of the conventional needle 50 is greatly dependent upon the guide holes 42a, 44a, and 31 for correcting the movement of the needle 50, and thus it is not independent of the guide holes 42a, 44a, and 31. That is, the repair and replacement of the needle is accompanied with, the repair and replacement of the plates 42 and 44 including the guide holes 42a, 44a, and 31 formed therethrough, and thus much manpower and time are required to maintain and repair the probe card with the increased cost for the maintenance and repair of the probe card

### BRIEF SUMMARY OF THE INVENTION

In view of the foregoing, the present invention has been made to solve the above-mentioned problems occurring in the prior art, and an object of the present invention is to provide a prove card that facilitates the wafer characteristic test by minimizing the movement of a needle.

Another object of the present invention is to provide a probe card that can prevent a lateral movement of a needle due to force being applied to the needle.

Still another object of the present invention is to provide a probe card that enables a needle to make a vertical movement by lowering the dependency upon guide holes for movement of the needle.

Still another object of the present invention is to provide a needle that can lower the dependency upon guide holes by providing one or more bending portions to the needle that is required to be in elastic contact with a test object.

In accordance with an embodiment of the present invention, there is provided a probe card including a main substrate including a probe circuit pattern formed thereon; a needle fixing block having a connection plate located on a lower surface of the main substrate and a tip plate apart from and parallel to the connection plate; and a needle having an elastic bending portion located between the connection plate and the tip plate, a tip portion extending from a lower end of the elastic bending portion and being projected from a lower surface of the tip plate, and a connection portion extending from an upper end of the elastic bending portion and being electrically connected to the prove circuit pattern; wherein a connection portion axis along the connection portion and a tip portion axis along the tip portion are formed to be apart from each other in the needle; the elastic bending portion has at least one bending portion formed by bending or folding; a outmost portion is formed in a position opposite to the tip portion around the connection portion axis in the bending portion; and a distance between the outmost portion of the elastic bending portion and the tip portion axis is set to be greater than a distance between the connection portion axis and the tip portion axis, so that the tip portion makes a substantially vertical movement.

Guide holes are formed through the connection plate and the tip plate so that the tip portion and the connection portion pass through the guide holes.

The bending portion is in a “U” shape, a “V” shape, a “⊃” shape, or a shape of a combination thereof.

The bending portion contains a connection portion point for connecting the connection portion to the bending portion and a tip portion point for connecting the tip portion to the bending portion.

A horizontal component of force acting on the connection portion point and a horizontal component of force acting on the tip portion point are offset from each other.

In accordance with another embodiment of the present invention, there is provided a probe card including a main substrate including a probe circuit pattern formed thereon; a needle fixing block having a connection plate located on a lower surface of the main substrate and a tip plate apart from and parallel to the connection plate; and a needle having an elastic bending portion located between the connection plate and the tip plate, a tip portion extending from a lower end of the elastic bending portion and being projected from a lower surface of the tip plate, and a connection portion extending from an upper end of the elastic bending portion and being electrically connected to the prove circuit pattern; wherein a connection portion axis along the connection portion and a tip portion axis along the tip portion are formed to be apart from each other in the needle; the elastic bending portion has at least one bending portion formed by bending or folding; a outmost portion is formed in a position opposite to the tip portion around the connection portion axis in the bending portion; and a distance between the outmost bending portion and the tip portion axis is set to be greater than a distance between the connection portion axis and the outmost bending portion, so that the tip portion makes a substantially vertical movement.

### BRIEF DESCRIPTION OF THE DRAWINGS

The disclosure may best be understood by reference to the following description taken in conjunction with the following figures:

FIG. 1 is a sectional view illustrating the structure in accordance with a conventional probe card;

FIG. 2 is a sectional view illustrating the structure of a probe card in accordance with an embodiment of the present invention;

FIG. 3 is a sectional view illustrating the structure and the installation structure of a needle in a probe card in accordance with an embodiment of the present invention; and

FIG. 4 is an enlarged view illustrating the structure of a needle in accordance with an embodiment of the present invention.

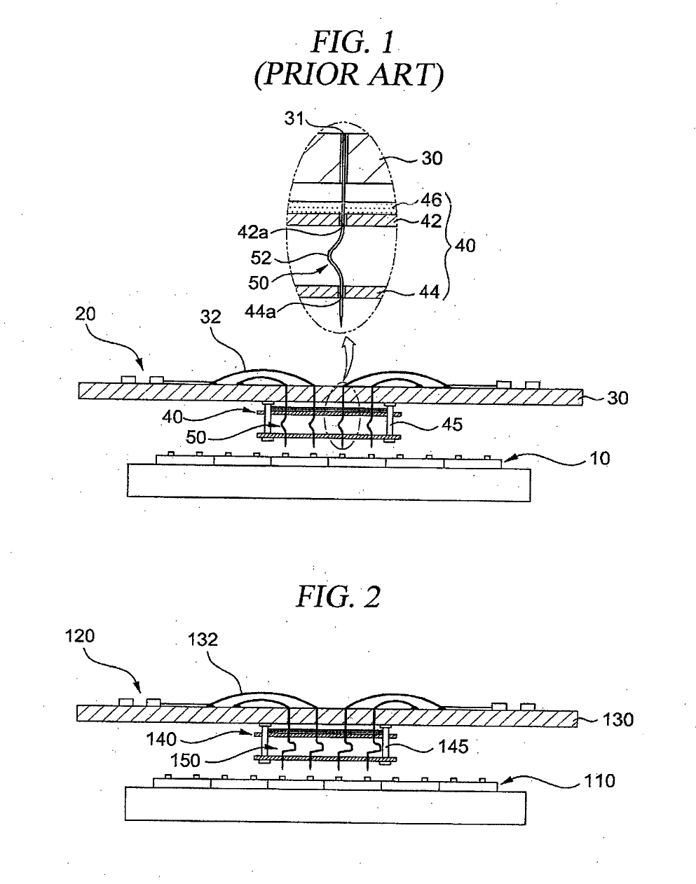

### DETAILED DESCRIPTION OF THE INVENTION

Hereinafter, embodiments of the present invention will be described in detail with reference to the accompanying drawings so that the present invention may be readily implemented by those skilled in the art. However, it is to be noted that the present invention is not limited to the embodiments but can be realized in various other ways. In the drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element. Further, the term “comprises or includes” and/or “comprising or including” used in the document means that one or more other components, steps, operation and/or existence or addition of elements are not excluded in addition to the described components, steps, operation and/or elements.

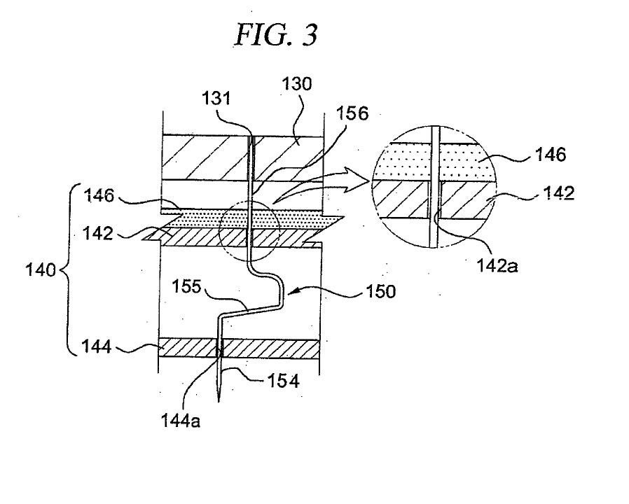

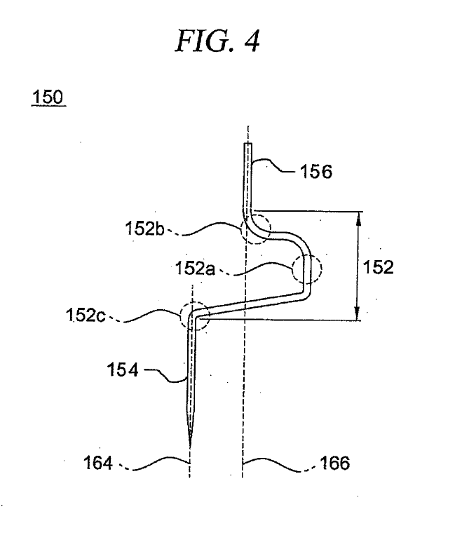

FIG. 2 is a sectional view illustrating the structure of a probe card in accordance with an embodiment of the present invention; FIG. 3 is a sectional view illustrating the structure and the installation structure of a needle in a probe card in accordance with the embodiment of the present invention; and FIG. 4 is an enlarged view illustrating the structure of a needle in accordance with the embodiment of the present invention.

As illustrated in FIG. 2, a probe card 120 vertically contacts a plurality of electrode pads (or circuit terminals) formed on a wafer 110 as a test object, and tests the electrical characteristics of chips in the wafer 110. The probe card 120 includes a main substrate 130; a needle fixing block 140 assembled on a lower surface of the main substrate 130; and an a plurality of needles 150 fixedly supported by the needle fixing block 140 thereby contacting the plurality of electrode pads (or circuit terminals) formed on the wafer as the test object.

The main substrate 130 may be a circle-shaped plate, and a probe circuit pattern (not shown) may be formed on the surface of the main substrate 130 or inside the main substrate 130. The main substrate 130 may be installed on a test head of which a test apparatus is connected to computer.

The needle fixing block 140 includes a pair of plates 142 and 144 disposed parallel to and apart from the main substrate 130, and the plates 142 and 144 are made of an insulating material. Specifically, the needle fixing block 140 includes the connection plate 142 and the tip plate 144 disposed apart from each other. The connection plate 142 is located under the main substrate 130, and the tip plate 144 is located parallel to the connection plate 142 by a predetermined distance. In addition, the needle fixing block 140 may further include a fastening member 145 for fixing the connection plates 142 and the tip plate 144 in a single unit. The fastening member 145 such as a bolt may be fastened to the main substrate 30 through the connection plates 142 and the tip plate 144.

The needles 150 are fixedly supported by the needle fixing block 140 while passing therethrough. An upper end of the needle 150 is electrically connected to the main substrate 130, and a lower end of the needle 150 is extended to a lower surface of the tip plate 144 and projected to an outside of the needle fixing block 140 so that the needle 150 vertically contacts the wafer 110. The needle 150 has an elastic bending portion 155 disposed between the connection plate 142 and the tip plate 144; a tip portion 154 extending in a single unit from a lower end of the elastic bending portion 155 and projecting from the lower surface of the tip plate 144; and a connection portion 156 extending in a single unit from an upper end of the elastic bending portion 155 and being electrically connected to a probe circuit pattern formed on the main substrate 130. A connection portion axis 166 and a tip portion axis 164 are parallelly apart from each other.

The elastic bending portion 155 is elastically moved when the tip portion 154 contacts the test object, and the probing of the tip portion 154 is elastically performed through the elastic bending portion 155. The elastic bending portion 155 serves to support the needle 150 on the needle fixing block 140 as well as contact the test object elastically. That is, the elastic bending portion 155 may be formed in diverse shapes in that both ends of the elastic bending portion can be supported between the connection plate 142 and the tip plate 144.

The elastic bending portion 155 may have a bending portion 152 formed by bending or folding the needle 150. In this case, the bending portion 152 may be in a “U” shape, a “V” shape, a “⊃” shape, or a shape of a combination thereof. Further, the elastic bending portion 155 may be in a wave shape.

The distance between a outmost portion 152a of the bending portion 152 and the tip portion axis 164 is set to be greater than the distance between the connection portion axis 166 and the tip portion axis 164. In this case, the outmost portion 152a is formed to face the tip portion axis 164 around the connection portion axis 166. Also, when a force is applied to the elastic bending portion 155 having the bending portion 152, the horizontal component of the force acting on a connection portion point 152b and the horizontal component of the force acting on a tip portion point 152c are offset from each other so that only the force in a vertical direction is applied to the tip portion 154, which actually moves vertically.

Also, the distance between the outmost portion 152a and the tip portion axis 164 is set to be greater than the distance between the connection portion axis 166 and the outmost bending portion 152a. As described above, the connection portion axis 166 and the tip portion axis 164 are apart from each other, and the horizontal component of the force acting on a tip portion point 152c are offset from each other so that only the force in a vertical direction is applied to the tip portion 154, which actually moves vertically.

Also, if a force is applied to the needle 150, the needle 150 elastically contacts with the test object so that tip portion 154 of the needle 150 is moved vertically. That is, the connection portion axis 166 and the tip portion axis 164 apart from each other so that the vertical movement of the tip portion 154 is not affected by the vertical movement of the connection portion 156. Accordingly, the vertical movement of the tip portion 154 that is required for the characteristic test of the object can be easily achieved.

In addition, the elastic bending portion 155 may be formed in diverse shapes so far as the tip portion 154 can move vertically, and the present invention is not limited or restricted by the shape and structure of the elastic bending portion 155.

Guide holes 142a, 144a, and 131 are formed through the connection plate 142 and the tip plate 144 so that the corresponding tip portion 154 and connection portion 156 can pass through the guide holes 142a, 144a, and 131. The guide holes 142a and 131 are arranged on the same line, and the guide hole 144a is arranged to be horizontally apart from the guide holes 142a and 131. That is, the guide holes 142a and 131 of the connection portion 156 are disposed to coincide with the connection portion axis 166, and the guide holes 144a of the tip portion 154 are disposed to coincide with the tip portion axis 164. The disposed guide holes 142a, 144a, and 131 serve to support the needle 150 so that the needle 150 is positioned in the needle fixing block 140.

As described above, in accordance with the embodiment of the present invention, the bending portion 152 is formed on the needle disposed in the needle fixing block 140. Accordingly, the needle can be vertically moved so that an accurate characteristic test is ensured and manpower and test time can be reduced with the improved workability and productivity. In particular, since the vertical movement of the conventional needle is determined by the alignment of the guide holes 142a, 144a, and 131 the needle 150 is greatly dependent upon the guide holes 142a, 144a, and 131. However, in accordance with the embodiment of the present invention, since the vertical movement of the needle becomes less dependent upon the guide holes 142a, 144a, and 131 due to the bending portion 152 of the elastic bending portion 155, the workability and productivity can be improved.

Also, in accordance with the embodiment of the present invention, when the repair and replacement of the needle 150 are required, the main plate 130 and the plates 142 and 144 having the guide holes 131, 142a and 144a, on which the dependency of the needle is lowered, can be easily repaired and replaced. Accordingly, the manufacturing process is simplified with improved workability and productivity.

In accordance with the embodiment of the present invention, it is exemplified that the needle fixing block 140 includes a pair of plates 142 and 144 disposed apart from each other. However, in accordance with another embodiment of the present invention, the needle fixing block 140 may be configured as a single plate that is apart from and parallel to the main substrate 130, and thus the needle may be provided between the main substrate and the single plate.

If a force is applied to the needle 150, the elastic bending portion 155 becomes in elastic contact with the test object, and the tip portion 154 of the needle 150 is moved vertically. That is, the connection portion axis and the tip portion axis differ from each other so that the vertical movement of the tip portion 154 is not affected by the movement of the connection portion 156. Accordingly, the vertical movement of the tip portion 154 that is required for the characteristic test of the object can be easily made.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A probe card comprising:
a main substrate including a probe circuit pattern formed thereon;
a needle fixing block including a connection plate located on a lower surface of the main substrate and a tip plate apart from and parallel to the connection plate; and
a needle including an elastic bending portion located between the connection plate and the tip plate, a tip portion extending from a lower end of the elastic bending portion and projecting from a lower surface of the tip plate, and a connection portion extending from an upper end of the elastic bending portion and being electrically connected to the prove circuit pattern,
wherein a connection portion axis along the connection portion and a tip portion axis along the tip portion are formed to be apart from each other in the needle;
the elastic bending portion has at least one bending portion formed by bending or folding;
a outmost portion is formed in a position opposite to the tip portion around the connection portion axis in the bending portion; and
a distance between the outmost portion and the tip portion axis is set to be greater than a distance between the connection portion axis and the tip portion axis, so that the tip portion makes a substantially vertical movement.

2. The probe card of claim 1, wherein guide holes are formed through the connection plate and the tip plate so that the tip portion and the connection portion pass through the guide holes.

3. The probe card of claim 1, wherein the bending portion is in a “U” shape, a “V” shape, a “⊃” shape, or a shape of a combination thereof.

4. The probe card of claim 3, wherein the bending portion has a connection portion point for connecting the connection portion to the bending portion and a tip portion point for connecting the tip portion to the bending portion.

5. The probe card of claim 4, wherein a horizontal component of force acting on the connection portion point and a horizontal component of force acting on the tip portion point are offset from each other.

6. A probe card comprising:
a main substrate including a probe circuit pattern formed thereon;
a needle fixing block including a connection plate located on a lower surface of the main substrate and a tip plate apart from and parallel to the connection plate; and
a needle including an elastic bending portion located between the connection plate and the tip plate, a tip portion extending from a lower end of the elastic bending portion and being projected from a lower surface of the tip plate, and a connection portion extending from an upper end of the elastic bending portion and being electrically connected to the prove circuit pattern,
wherein a connection portion axis along the connection portion and a tip portion axis along the tip portion are formed to be apart from each other in the needle;
the elastic bending portion has at least one bending portion formed by bending or folding;
a outmost portion is formed in a position opposite to the tip portion around the connection portion axis in the bending portion; and
a distance between the outmost portion and the tip portion axis is set to be greater than a distance between the connection portion axis and the outmost portion, so that the tip portion makes a substantially vertical movement.

7. The probe card of claim 6, wherein guide holes are formed through the connection plate and the tip plate so that the tip portion and the connection portion pass through the guide holes.

8. The probe card of claim 6, wherein the bending portion is in a “U” shape, a “V” shape, a “⊃” shape, or a shape of a combination thereof.

9. The probe card of claim 8, wherein the bending portion has a connection portion point for connecting the connection portion to the bending portion and a tip portion point for connecting the tip portion to the bending portion.

10. The probe card of claim 9, wherein a horizontal component of force acting on the connection portion point and a horizontal component of force acting on the tip portion point are offset from each other.
